(19) United States
(12) Patent Application Publication
(10) Pub. No.: US 2014/0220489 A1
(43) Pub. Date: Aug. 7, 2014

(54) METHOD FOR PROCESSING SAMPLE AND SAMPLE PROCESSING APPARATUS

(71) Applicant: HITACHI HIGH-TECHNOLOGIES CORPORATION, Tokyo (JP)

(72) Inventors: Yutaka KOZUMA, Kudamatsu-shi (JP); Hiroaki OIZUMI, Tokyo (JP); Naoki YASUI, Kudamatsu-shi (JP); Seiichi WATANABE, Houfu-shi (JP)

(73) Assignee: HITACHI HIGH-TECHNOLOGIES CORPORATION, Tokyo (JP)

(21) Appl. No.: 13/792,325

(22) Filed: Mar. 11, 2013

(30) Foreign Application Priority Data
Feb. 4, 2013 (JP) 2013-019066

(51) Int. Cl. G03F 7/004

(52) U.S. Cl. CPC G03F 7/004
USPC 430/270.1; 156/345.29

(57) ABSTRACT

Long-period roughness in patterned resist is reduced in a manufacturing process of a sample such as a semiconductor device. A method for processing a sample to be processed, with patterned resist, in a sample processing apparatus includes: disposing the sample to be processed, with the patterned resist on the stage in the processing chamber; supplying silicon tetrachloride (SiCl₄) or hydrobromide (HBr) into the processing chamber as processing gas; holding the pressure of the processing chamber in the range of 1 Pa to 10 KPa; exciting the processing gas by irradiating the vacuum ultraviolet light having a wavelength of 200 nm or less to the processing gas; reacting an element contained in the excited processing gas with the pattern resist of the sample, and curing the resist.

### CLAIM OF PRIORITY

The present application claims priority from Japanese Patent Application 2013-019066 filed on Feb. 4, 2013, the content of which is hereby incorporated by reference into this application.

### FIELD OF THE INVENTION

The present invention relates to a method for processing a sample and a sample processing apparatus, and more particularly, to a method for processing a sample and a sample processing apparatus that are suitable to irradiate vacuum ultraviolet light to a sample such as a semiconductor device substrate and process a sample with a resist pattern.

### BACKGROUND OF THE INVENTION

“Chapter 13. WG11 Metrology (Measurement)” (reported by the Semiconductor Technology Roadmap Expert Committee in 2004, pp 233 to 239) relates to a semiconductor device and discloses standardization of a measurement method of pattern edge-shaped roughness or an influence of gate line roughness exerted on transistor performance. Further, as related art that reduces resist roughness, International Publication No. WO 2011/062162 (Corresponding US 2012/0228261 A1) discloses a technology that uses a sample processing apparatus that includes a container connected with a gas supply apparatus and a vacuum exhaust apparatus, in which an inner part is able to be depressurized, a plasma light source constituted by a plasma generating means generating plasma and emitting a vacuum ultraviolet (hereinafter, referred to as “VUV”) light having a wavelength of 200 nm or less in the container, and a VUV light transmission filter having a larger outer diameter than a sample to be processed, which transmits VUV light having a wavelength of 200 nm or less without transmitting electrons, ions, and radicals in plasma, between the plasma light source and a stage on which the sample to be processed is placed in the container, and irradiates VUV light onto the entire surface of a wafer with high reproducibility and VUV-processes the wafer with high reproducibility. International Publication No. WO 2011/062162 discloses a technology that depressurizes a processing space between the VUV transmission filter and the stage at high vacuum of approximately 10⁻³ Pa and thereafter, the wafer is processed by introducing hydrobromide (HBr) as the processing gas.

Further, a technology related to this type may be disclosed in Japanese Patent Application Laid-Open Publication No. 2005-197348 or Japanese Patent Application Laid-Open Publication No. 2005-158796. Japanese Patent Application Laid-Open Publication No. 2005-197348 discloses a technology that irradiates ultraviolet light having a frequency of 200 nm or less to the wafer. Japanese Patent Application Laid-Open Publication No. 2005-158796 discloses a technology that activates NmHn gas in the processing space, for example, asking-removes resist injected with ions. Japanese Patent Application Laid-Open Publication No. Hei8 (1996)-153493 discloses an apparatus in which a plurality of cylindrical dielectric barrier discharge lamps is disposed as a light source of ultraviolet light and excimer light is extracted.

### SUMMARY OF THE INVENTION

In recent year, with minuteness of a semiconductor device, an influence of vibration of a line pattern edge shape of a resist mask which exerts on device performance has been exposed. Pattern edge-shaped roughness is expressed by using line edge roughness (LER) or line width roughness (LWR) as an index. An influence of the LER or LWR on the device performance is largely divided into short-period roughness F1 and long-period roughness F2 illustrated in FIG. 11. The former short-period roughness F1 is the LWR which has a shorter period than the width of respective transistors 51 and locally shortens a gate length of a gate 55 to thereby cause a short channel effect, increase leak current, lower limit voltage. The latter long-period roughness F2 is the LWR which has a longer period than the width of the respective transistors 51 and causes vibration of the gate length throughout a plurality of transistors 51 and becomes a cause of non-uniformity of performances of the respective transistors in an LSI circuit. As reported in “Chapter 13. WG11 Metrology (Measurement)” (reported by the Semiconductor Technology Roadmap Expert Committee in 2004, pp 233 to 239), in the case of the short-period roughness, an influence of roughness in respective transistor areas on the device performance is comparatively small and still, the non-uniformity throughout the plurality of transistors caused by the long-period roughness causes a problem in terms of the device performance. However, it is mentioned that it is difficult to reduce the long-period roughness in the related art and even in the aforementioned related art, a method or a processing apparatus for reducing the long-period roughness is not commented.

The present invention has been made in an effort to provide a method for processing a sample and a sample processing apparatus that can reduce long-period roughness in patterned resist, in a manufacturing process of a sample such as a semiconductor device.

A representative invention will be described below. A method for processing a sample to be processed, with patterned resist, in a sample processing apparatus including a light source emitting vacuum ultraviolet light, a processing chamber having a stage therein and capable of irradiating the vacuum ultraviolet light having a wavelength of 200 nm or less to the sample to be processed, which is disposed on the stage, a processing gas supply apparatus introducing processing gas into the processing chamber, and a vacuum exhaust apparatus connected to an outlet port of the processing chamber, includes: disposing the sample to be processed, with the patterned resist on the stage in the processing chamber; supplying silicon tetrachloride (SiCl₄) or hydrobromide (HBr) into the processing chamber as processing gas; and exciting the processing gas in some of the vacuum ultraviolet light by irradiating the vacuum ultraviolet light to the processing gas in the processing chamber, reacting an element of Si or Br contained in the excited processing gas and the resist with the remaining ultraviolet light, and alleviating stress generated in the resist while curing the resist.

According to an aspect of the present invention, as a sample processing apparatus, a sample processing apparatus suitable to uniformly process a sample to be processed is provided. Further, according to an operation of the present invention, stress generated in the sample to be processed can be alleviated, long-period roughness having a period of 30 nm of a minute line patterned by an exposure apparatus, which was known to be difficult to reduce in the related art can be reduced, and unevenness which occurs on the surface or the side of a resist film formed on a semiconductor substrate can be suppressed with high-precision, thereby implementing an etching process.

### BRIEF DESCRIPTION OF THE DRAWINGS

FIG. 1 is a longitudinal cross-sectional view of a sample processing apparatus according to a first embodiment of the present invention;

FIG. 2A is a plan view illustrating, in detail, a gas supply plate according to the first embodiment;

FIG. 2B is a longitudinal cross-sectional view illustrating, in detail, the gas supply plate according to the first embodiment;

FIG. 3A is a diagram illustrating a frequency analysis result of resist roughness illustrating an effect of the first embodiment;

FIG. 3B is a diagram illustrating a frequency analysis result of resist roughness in Comparative Example;

FIG. 4 is a diagram illustrating a stress evaluation result of a resist material illustrating an application effect of the first embodiment;

FIG. 5 is a diagram illustrating an XPS analysis result illustrating the application effect of the first embodiment;

FIG. 6 is a schematic diagram illustrating resist states before processing and after processing of the first embodiment;

FIG. 7A is a longitudinal cross-sectional view of a sample processing apparatus according to a second embodiment of the present invention;

FIG. 7B is a diagram illustrating a frequency analysis result of resist roughness illustrating an application effect of the second embodiment;

FIG. 8 is a longitudinal cross-sectional view of a sample processing apparatus according to a third embodiment of the present invention;

FIG. 9 is a longitudinal cross-sectional view of a sample processing apparatus according to a fourth embodiment of the present invention;

FIG. 10A is a longitudinal cross-sectional view of a sample processing apparatus according to a fifth embodiment of the present invention;

FIG. 10B is a plan view illustrating, in detail, a gas supply ring according to the fifth embodiment; and

FIG. 11 is a schematic diagram illustrating resist roughness which is a problem of related art.

### DETAILED DESCRIPTION OF THE PREFERRED EMBODIMENTS

According to a method for processing resist by a representative embodiment of the present invention, a sample having resist with a minute pattern by an exposure apparatus is disposed in a processing chamber, silicon tetrachloride (SiCl₄) or hydrobromide (HBr) as processing gases are supplied into the processing chamber and maintaining at predetermined pressure, VUV light having a wavelength of 200 nm or less is irradiated to the processing gases to excite the processing gases in some of the VUV light, and an element contained in the excited processing gas and patterned resist photo-react with the remaining VUV light and stress which occurs in the resist is alleviated.

According to an apparatus for processing resist by a representative embodiment of the present invention, the apparatus includes a light source that emits VUV light having a wavelength of 200 nm or less, a stage where a wafer is disposed, a processing chamber having the stage therein and capable of irradiating the VUV light to the wafer disposed on the stage, and a processing gas supplying means introducing silicon tetrachloride (SiCl₄) or hydrobromide (HBr) as processing gases into an irradiation area of VUV light in a processing chamber, in which some of the VUV light generated from a light source unit is used to excite the processing gases and the remaining VUV light is used to react with an element contained in the excited processing gases and a resist pattern.

### First Embodiment

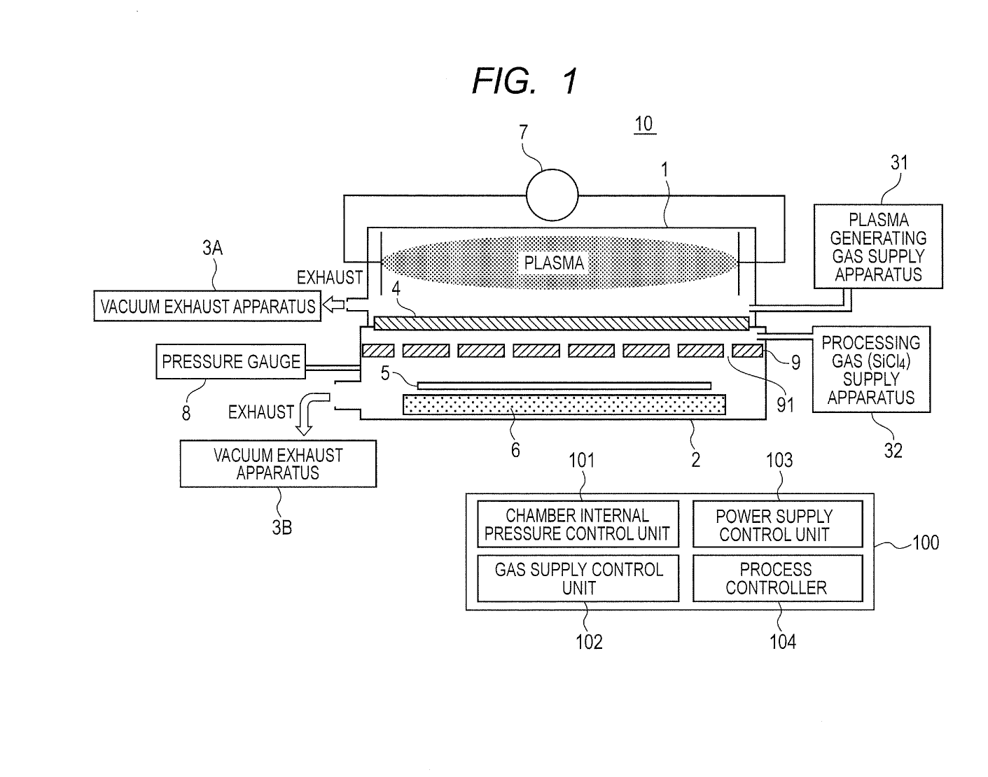

Hereinafter, a first embodiment of the present invention will be described with reference to FIGS. 1 to 6. FIG. 1 is a longitudinal cross-sectional view of a sample processing apparatus 10 of the present invention. The sample processing apparatus used to process resist during a manufacturing process of a semiconductor device includes a plasma generation container 1 generating plasma by supplying high-frequency energy to gas in a vacuum chamber and a processing container 2 provided below the plasma generation container 1 as a light source unit. That is, the sample processing apparatus 10 of the first embodiment is a resist processing apparatus in which a VUV light source is configured by plasma. A parallel plate discharge electrode connected to a high-frequency power supply 7 is provided in the plasma generation container 1 constituting the VUV light source unit, and a plasma generation gas supply apparatus 31 for supplying gas for generating plasma is connected to a space for generating plasma in the plasma generation container 1. Types of gases used to generate plasma includes gas generating VUV light having a wavelength of 172 nm or less, for example, single gas such as hydrogen gas, helium gas, argon gas, xenon gas, hydrobromide gas, and nitrogen gas and mixed gas containing the gases. As a method for generating plasma in the plasma generation container 1, parallel plate discharge is used in the plasma generation container 1, but uniform plasma may be just generated, in the first embodiment. As a method for plasma discharge, for example, dielectric barrier discharge, microwave discharge, ECR discharge, ICP discharge, magnetron discharge, halo-cathode discharge, DC discharge, and the like may be used. A first vacuum exhaust apparatus 3A is connected to the plasma generation container 1 through an air outlet port.

The plasma generation container 1 and the processing container 2 are airtightly partitioned by a VUV transmission window 4. The VUV transmission window 4 is made of synthetic quartz, MgF₂, CaF₂, LIF, sapphire, and the like which the VUV light having the wavelength of 172 nm generated by the plasma is able to pass through.

A wafer stage 6 is provided in the processing chamber in the processing container 2 to be opposite to the VUV transmission window 4. A wafer 5 where a minute resist pattern is formed by an exposure apparatus, which is a sample to be processed, is placed on the wafer stage 6.

A gas supply plate 9 is provided below the VUV transmission window 4 and made of a material which the VUV light having the wavelength of 172 nm is able to pass through, similarly to the VUV transmission window 4. A first processing gas supply apparatus 32 for supplying processing gas is connected between the VUV transmission window 4 and the gas supply plate 9, and silicon tetrachloride (SiCl₄) is supplied between silicon tetrachloride (SiCl₄) as processing gas. The air outlet port is provided in the processing container 2, a second vacuum exhaust apparatus 3B is connected to the processing container 2 through a pressure control valve (not illustrated), and the processing chamber of the processing container 2 is depressurized. A pressure gauge 8 is mounted below the gas supply plate 9 of the processing container 2, and processing pressure in the processing container 2 is monitored and maintained at desired pressure.

The sample processing apparatus 10 includes a control unit 100 configured by a computer. The control unit 100 includes a chamber internal pressure control unit 101, a gas supply control unit 102, a power supply control unit 103, and the like, which are controlled by a process controller 104.

The chamber internal pressure control unit 101 maintains the insides of the plasma generation container 1 and the processing container 2 at a predetermined vacuum level by controlling the first vacuum exhaust apparatus 3A and the second vacuum exhaust apparatus 3B 14. The gas supply control unit 102 controls each of a flow of gas supplied into each of the plasma generation container 1 from a first gas supply apparatus and the processing container 2 from a second gas supply apparatus. The power supply control unit 103 controls electric power applied to the parallel plate discharge electrode by controlling a power supply 7.

A plasma generating space in the plasma generation container 1 is first depressurized to high vacuum of approximately 10⁻³ Pa by the first vacuum exhaust apparatus 3A, and thereafter, the plasma generating gas is supplied to this space, and the pressure of this space is controlled to pressure suitable to generate plasma at approximately 1

Pa to 10 Pa. Meanwhile, a processing space in the processing container 2 is first depressurized to the high vacuum of approximately 10⁻³ Pa by the second vacuum exhaust apparatus 3B and thereafter, resist processing gas is supplied to this space and the pressure of this space is controlled to pressure suitable to process resist.

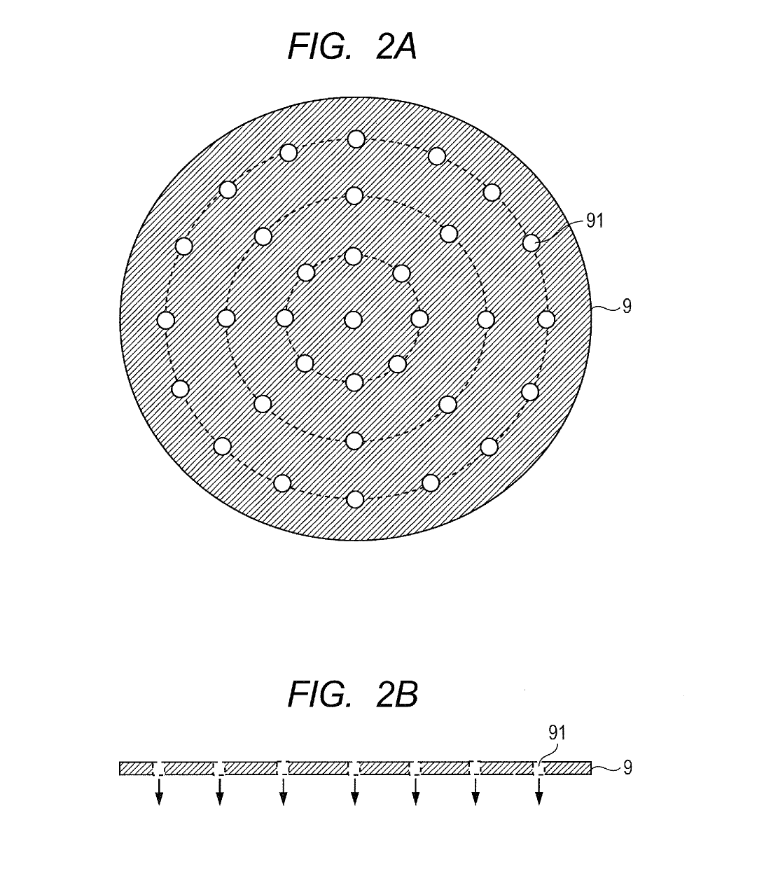

FIGS. 2A and 2B illustrate, in detail, the gas supply plate 9. A plurality of gas supply holes 91 is provided in the gas supply plate 9 to uniformly supply gas to the wafer 5.

In the VUV-processing, first, the pressure of this space is depressurized to the high vacuum of approximately 10⁻³ Pa through the vacuum outlet port provided in the processing container 2 by the second vacuum exhaust apparatus 3B, gas which remains in the processing container 2 is vacuum-exhausted, the processing gas is introduced, and then the VUV light is irradiated to the wafer 5 of the processing chamber under pressure of 1 Pa to 10 KPa. The processing gas is introduced from the first processing gas supply apparatus 32 and uniformly supplied onto the wafer 5 through the gas supply plate 9 installed in the processing container 2 in order to uniformly process the wafer. In the sample processing apparatus of the embodiment, which includes the gas supply plate 9 which the VUV light is able to pass through, the processing gas supplied from the first processing gas supply apparatus 32 is first excited between the VUV transmission window 4 and the gas supply plate 9. The excited processing gas is uniformly emitted onto a plane of the wafer 5 from the plurality of supply holes provided on the gas supply plate 9. Further, in the sample processing apparatus, by controlling a mass flow controller (not illustrated) provided in the first processing gas supply apparatus 32, the pressure gauge 8, and a pressure control valve (not illustrated) of the exhaust apparatus, it is possible to perform both wafer processing performed while allowing the processing gas to flow at a desired flow amount and wafer processing performed without causing gas to flow while charging the processing gas at desired pressure and fixing the pressure at the desired pressure.

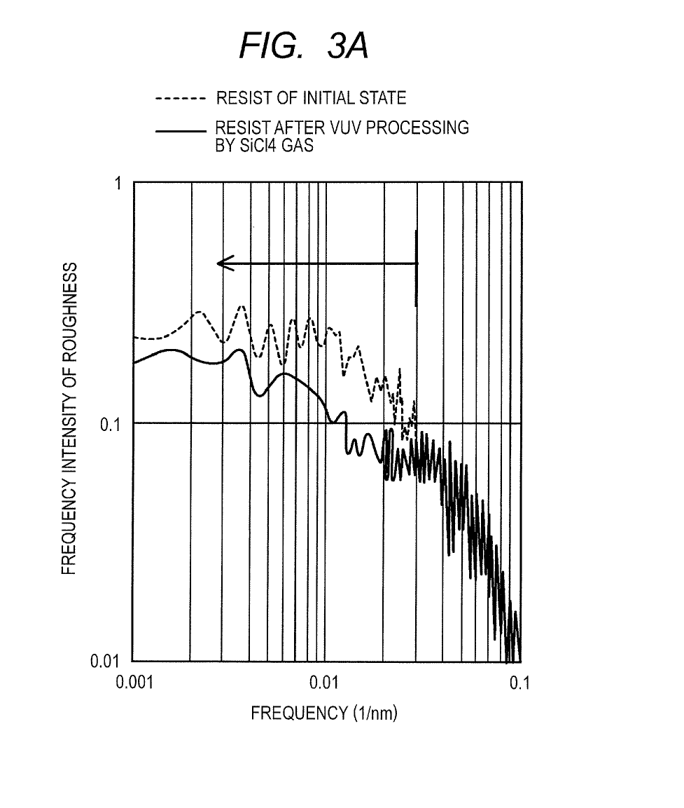

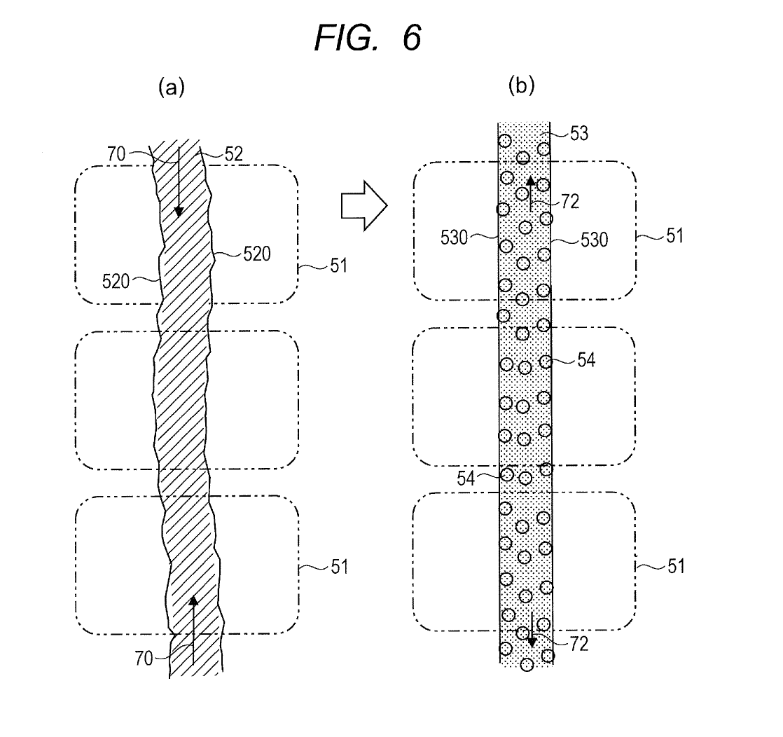

Subsequently, a case in which the patterned resist is cured with silicon tetrachloride (SiCl₄) as the processing gas by the sample processing apparatus configured as above will be described with reference to FIG. 3 or 6. Further, in this application example, while the wafer is set as an ArF resist sample, the processing container 2 is depressurized to the high vacuum, silicon tetrachloride (hereinafter, referred to as “SiCl₄”) as the processing gas is introduced into the processing chamber, the pressure of the processing chamber is increased up to desired pressure (in this case, 0.3 KPa), and then the SiCl₄ gas flows (in this case, 300 SCCM), VUV light emitted from plasma is irradiated to the wafer 5.

According to a study result of inventor, the pressure of the processing chamber is controlled to appropriate pressure while the SiCl₄ gas is introduced as the processing gas and the VUV is irradiated to the SiCl₄ gas, and as a result, the SiCl₄ gas absorbs some of the VUV light to be dissociated, the remaining VUV light which is not absorbed by the gas promotes reaction of atoms dissolved from the gas and resist, and the dissolved atoms are attached and absorbed to a resist film. In the case where the processing space is depressurized at the high vacuum of approximately 10⁻³ Pa, the VUV light is not absorbed in the gas of the processing space, and as a result, the gas is not dissociated, 100% VUV light is irradiated to the resist film, and the dissociated atoms and the resist do not react with each other. However, in the case where the processing space is depressurized at appropriate pressure, for example, under vacuum of 1.0 KPa, the gas absorbs approximately 10% of the VUV light to be dissociated, and the remaining 90% VUV light and the resist react with each other, and as a result, the dissociated atoms are attached onto the resist film. Meanwhile, in the case where a vacuum level of the processing space is low, since the number of molecules of processing gas which exist in the processing space is large, the 100% VUV light is absorbed in the gas, and the reaction between the VUV light and the resist is not promoted. According to a study of the present invention, processing of the resist by the VUV light is performed while the processing space is depressurized to vacuum of 1 Pa to 10 KPa to reduce long-period roughness.

FIG. 3A illustrates a frequency analysis result of initial roughness of ArF pattern and ArF resist in which roughness is reduced by VUV curing by using the sample processing apparatus of the first embodiment. The analysis result is a result in a state where the processing gas is the SiCl₄ gas and the processing space is depressurized to 0.3 KPa. Meanwhile, FIG. 3B illustrates a frequency analysis result of initial roughness of the ArF pattern and ArF resist in which roughness is reduced by plasma curing which is generally known as a method for reducing roughness, for comparison. Horizontal axes of FIGS. 3A and 3B represent frequencies, and vertical axes represent the intensities (relative amount) of roughness frequency which is Fourier transformed. As illustrated in FIG. 3A, in regard to the ArF pattern processed in the sample processing apparatus of the first embodiment, long-period roughness having a frequency of 0.03 (1/nm) or less, that is, a period of 30 nm or more is remarkably reduced as compared with the initial roughness of the ArF pattern, as illustrated by arrow in the figure. Meanwhile, as illustrated FIG. 3B, in regard to the ArF pattern in which the plasma curing process used generally is performed, variation amount before and after processing is small as compared with the initial roughness of the ArF pattern. For this reason, in the sample processing apparatus of the first embodiment, after SiCl₄ is supplied as the processing gas and the processing space is maintained at desired pressure, the VW curing is performed, and as a result, it can be seen that there is an effect to reduce the long-period roughness which is known to be difficult from the related art. As the test result, the pressure of the processing space may be preferably in the range of 1 Pa to 10 KPa.

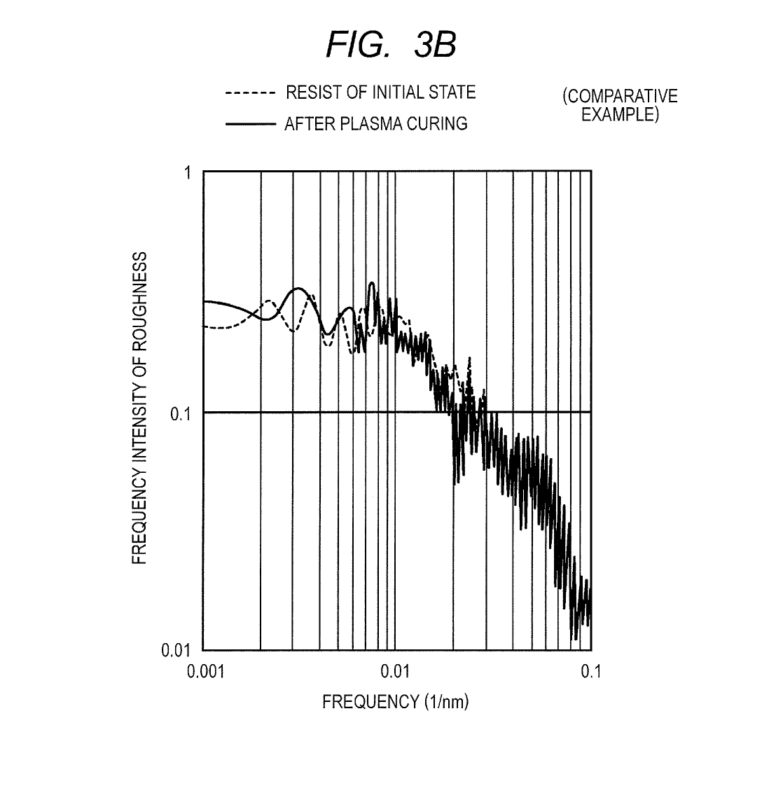

Subsequently, FIG. 4 illustrates a result of measuring stress generated in resist with respect to two types of ArF resists processed under the same condition as FIG. 3A. A result of performing only VUV irradiation without supplying SiCl₄ as the processing gas is also illustrated with respect to each resist, for comparison. Herein, a vertical axis of a graph represents a stress variation amount from an initial stage, Δσ≧0 represents tension stress, and Δσ<0 represents compression stress.

As illustrated in the graph of FIG. 4, in general VW curing, the tension stress is generated commonly to two types of resists. In the case where the tension stress is generated, a problem that a distance of a resist pattern end is increased occurs, and high-precision etching is interrupted. According to another consideration of the inventors, a result that the tension stress is generated with respect to even the resist subjected to the plasma curing is acquired, similarly to the resist subjected to VUV curing.

Meanwhile, in performing VUV curing by supplying SiCl₄ to the sample processing apparatus of the present invention, tension stress generated in the film is remarkably improved. For this reason, by the sample processing apparatus of the first embodiment, VUV curing is performed by supplying SiCl₄ and setting the pressure of the processing space in the range of 1 Pa to 10 KPa, and as a result, the long-period roughness deteriorates and the tension stress generated in the resist film is alleviated.

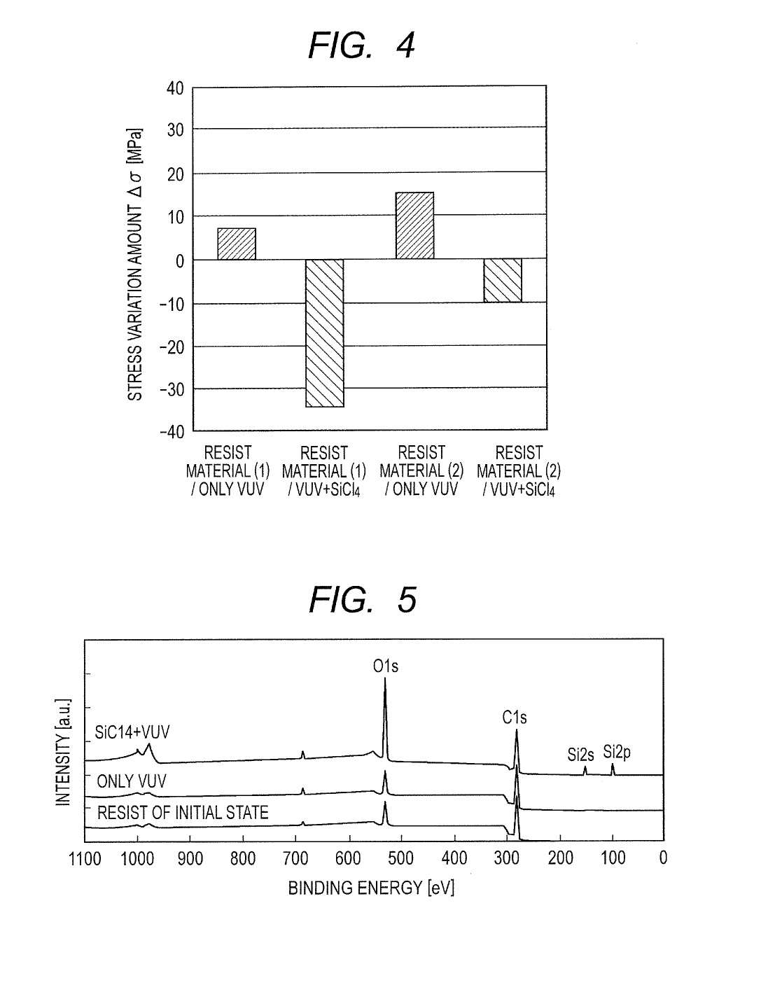

Subsequently, FIG. 5 illustrates a result of analyzing a composition of the resist film by X-ray photoelectron spectroscopy (XPS). FIG. 5 illustrates composition analysis results of unprocessed resist, resist subjected to general VUV processing, and resist subjected to VUV curing by supplying SiCl₄ to the VUV light processing apparatus of the first embodiment, from the bottom. As the result of the composition analysis by the XPS, with respect to the resist in which SiCl₄ is supplied as the processing gas and VUV curing is performed, a peak corresponding to Si is detected and an Si atom of 10 atomic % or more is included in the film.

From this result, as an operation to perform VUV curing by supplying SiCl₄ to the VUV light processing apparatus of the first embodiment and setting the pressure of the processing space in the range of 1 Pa to 10 KPa, the Si atom is supplied to the resist film from SiCl₄, and as a result, the long-period roughness is reduced and the stress generated in the film is alleviated. Further, this result illustrates that a light excitation reaction occurs in the processing chamber by the VUV light having the frequency of 172 nm, which is generated from the light source unit by supplying SiCl₄ having an absorption short wavelength of 163 nm as the processing gas to the sample processing apparatus of the first embodiment.

A reason for reducing the long-period roughness will be described with reference to FIG. 6, from the aforementioned result. FIG. 6A illustrates an initial state of resist and FIG. 6B illustrates resist in which VUV curing is performed by supplying the processing gas and setting the pressure of the processing space in the range of 1 Pa to 10 KPa and roughness is reduced. In the initial state of FIG. 6A, surfaces 520a and 520b of a resist 52 patterned by an exposure apparatus in order to process a gate of a transistor 51 have short-period roughness and long-period roughness. In order to reduce roughness, in the case where general curing processing using plasma or VUV processing that does not supply the processing gas is performed, a carbon component C is separated from the resist, and tension stress is generated in the resist as illustrated by an arrow 70. In this regard, in the VUV processing that supplies the processing gas of the first embodiment, SiCl₄ of the processing gas is dissociated into Si and Cl by some of the VUV light supplied from the light source, Si 54 is attached to the surfaces 530a and 530b of a resist 53, or permeates into the resist film, and the dissociated Si 54 is coupled with C of the resist.

As described above, in the case where the disassociation of the processing gas depends on the pressure of the processing space and the processing space is depressurized at the high vacuum of approximately 10⁻³ Pa, the gas is not dissociated and the VUV light is all irradiated to the resist film. Meanwhile, in the case where the processing space is depressurized at vacuum of 1 Pa to 10 KPa, the gas is dissociated by the VUV light and the atom is attached to the resist film.

As a result, compression force is generated in the resist as illustrated by an arrow 72 by attaching Si to the resist or coupling Si with the resist, as illustrated in FIG. 6B. The compression force is generated in a direction opposite to the tension stress, and as a result, the stress generated in the resist is alleviated and the long-period roughness having a period of 30 nm or more of a minute line is reduced. That is, according to the first embodiment, the short-period roughness and the long-period roughness of the patterned resist are reduced.

### Second Embodiment

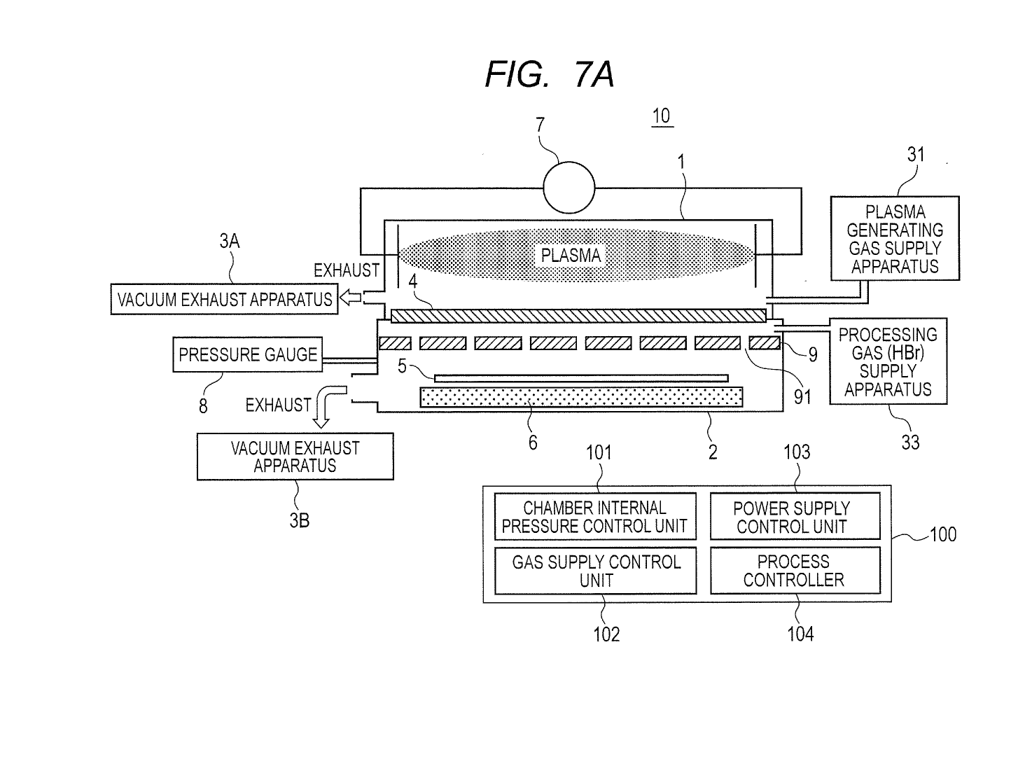

Subsequently, a second embodiment of the present invention will be described with reference to FIGS. 7A and 7B. FIG. 7A is a longitudinal cross-sectional view of a sample processing apparatus according to a second embodiment of the present invention. In the second embodiment, hydrobromide (HBr) as processing gas is supplied from a second processing gas supply apparatus 33 to a processing container 2 of a sample processing apparatus 10. Other components and functions are the same as those of the first embodiment. Similarly to the first embodiment, while a wafer is set as an ArF resist sample, the processing container 2 is depressurized to high vacuum, and thereafter, hydrobromide (HBr) is introduced into the processing container 2 from the second processing gas supply apparatus 33, a processing space is increased up to desired pressure in the range of 1 Pa to 10 KPa as the pressure of the processing chamber, and HBr gas flows (in this case, 300 SCCM), processing is performed with VUV light emitted from plasma.

FIG. 7B illustrates a frequency analysis result of initial roughness of ArF pattern and ArF resist in which roughness is reduced by VUV curing by using the sample processing apparatus of the second embodiment. The analysis result is a result in a state where the processing gas is the HBr gas and the processing space is depressurized to 350 Pa.

As illustrated in FIG. 7B, even in the case where HBr is used as the supplied processing gas, in regard to an ArF pattern sample processed in the sample processing apparatus, long-period roughness having a frequency of 0.03 (1/nm) or less, that is, a period of 30 nm or more is remarkably reduced as compared with the initial roughness of the ArF pattern, similarly to the first embodiment. Further, even in the case where hydrobromide (HBr) is introduced, HBr is introduced as the processing gas, and as a result, tension stress generated in a film is alleviated, similarly to the first embodiment. In addition, in a result of performing XPS analysis with respect to resist in which HBr is supplied as the processing gas and VUV curing is performed, a peak corresponding to bromide (Br) is detected and a Br atom of 10 atomic % is included in the film. From this result, in the second embodiment, as an operation to perform VUV curing by supplying HBr while maintaining the pressure of the processing space in the range of 1 Pa to 10 KPa, the same effect as the first embodiment is achieved, HBr is dissociated into H and Br by light excitation by VUV light, and Br is supplied to and acts on the resist film, and as a result, the long-period roughness is reduced and the stress generated in the film is alleviated.

### Third Embodiment

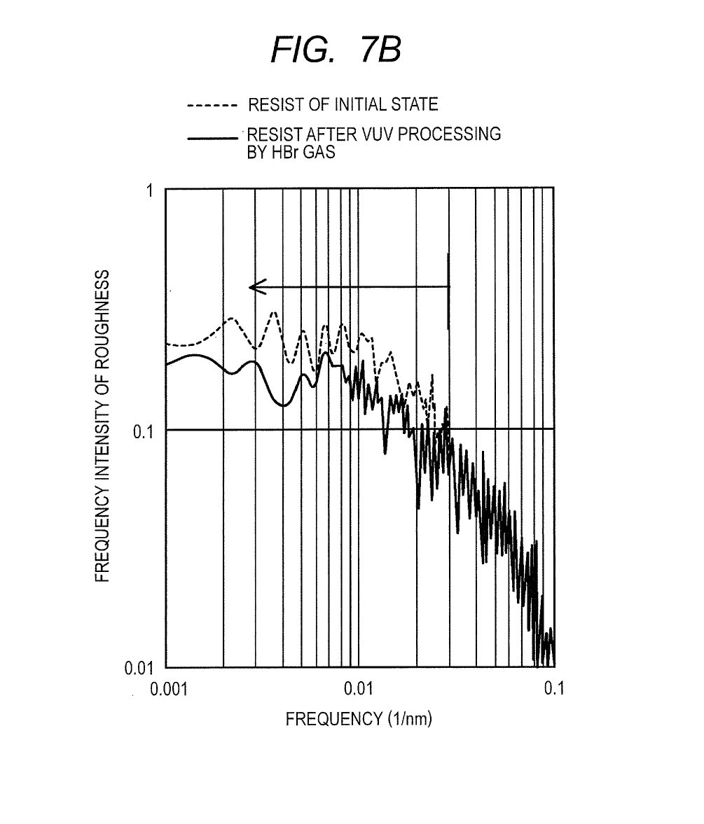

FIG. 8 is a cross-sectional view of a VUV light processing apparatus of a third embodiment of the present invention. The third embodiment discloses a sample processing apparatus using an excimer lamp instead of plasma as a light source of the VUV light processing apparatus. Other components and functions are the same as those of the first and second embodiments, and SiCl₄ is supplied from a first processing gas supply apparatus 32 or hydrobromide (HBr) is supplied from a second processing gas supply apparatus 33, to a processing container 2, as processing gas. In this case, a plurality of cylindrical excimer lamps 12 using dielectric barrier discharge having a wavelength of 200 nm or less is installed in a lamp house 11. The cylindrical excimer lamps 12 include an Xe excimer lamp emitting excimer light having a wavelength of 172 nm, an Ar excimer lamp emitting excimer light having a wavelength of 126 nm, a Kr excimer lamp emitting excimer light having a wavelength of 146 nm, an ArF excimer lamp emitting excimer light having a wavelength of 193 nm, and the like. The lamp house 11 and the processing container 2 are partitioned by a VUV transmission window 4, similarly to in FIG. 1. A gas inlet port (not illustrated) and a gas outlet port (not illustrated) are provided in the lamp house 11, and N₂ gas is introduced and the inside of the lamp house 11 is substituted by N₂, thereby suppressing VUV light from being decreased by O₂ in an atmosphere.

A part below the VUV transmission window 4 has the same structure as the VUV transmission window 4 of the first embodiment or the second embodiment, and the processing gas of silicon tetrachloride (SiCl₄) or hydrobromide (HBr) supplied from the second or third gas supply apparatus is uniformly supplied onto a wafer 5 through a gas supply plate 9. The pressure of the processing container 2 is maintained in the range of 1 Pa to 10 KPa. As a result, even in the case where the cylindrical excimer lamp 12 is used as the light source, uniformity of an internal atmosphere of the processing container 2 is improved. As a result, the processing gas is dissociated by VUV light and an atom is attached to a resist film together therewith, similarly to the first embodiment or the second embodiment. Therefore, stress generated in a sample to be processed may be alleviated, long-period roughness may be significantly reduced, and unevenness generated on the surface or the side of a resist film formed on a semiconductor substrate is suppressed with high precision, and as a result, etching is achieved.

### Fourth Embodiment

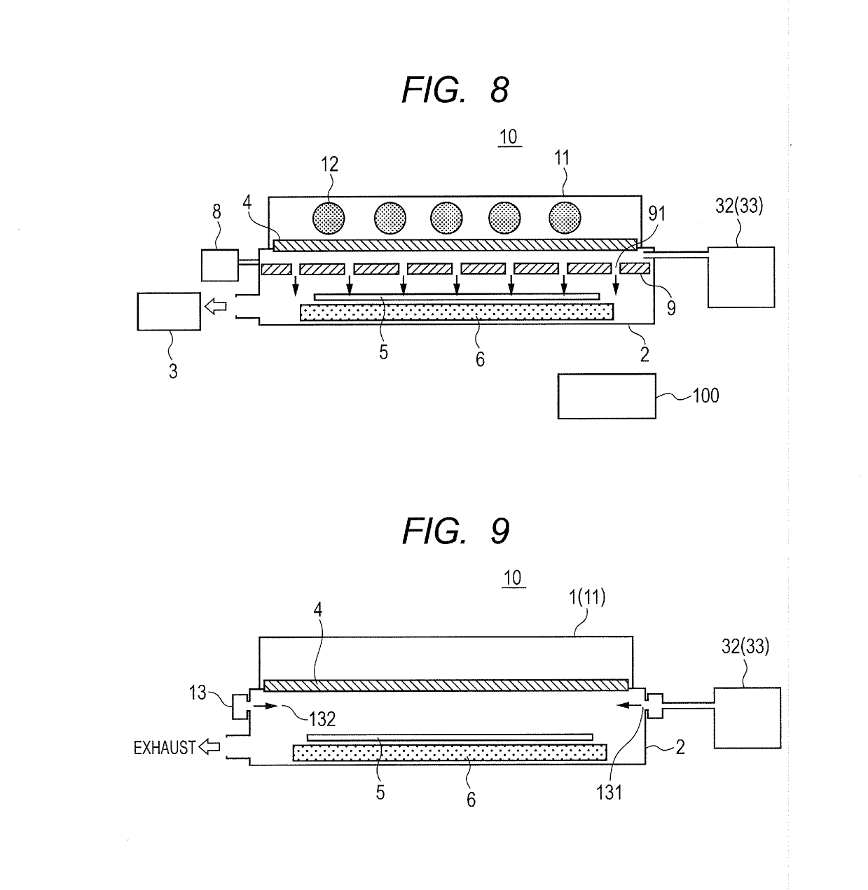

A fourth embodiment of the present invention will be described with reference to FIG. 9. In the fourth embodiment, another processing gas supply method that improves uniformity of a processing atmosphere is adopted, which is different from the gas supply plate disclosed in the first and second embodiments. FIG. 9 is a longitudinal cross-sectional view of a sample processing apparatus according to a fourth embodiment. In the sample processing apparatus of the fourth embodiment, a light source unit 10 and a processing container 2 are partitioned by a VUV transmission window 4, similarly to in FIG. 1. The light source unit 10 corresponds to the plasma light source 1 disclosed in the first embodiment or the excimer lamp light source 11 disclosed in the third embodiment. SiCl₄ is supplied from a first processing gas supply apparatus 32 or hydrobromide (HBr) is supplied from a second processing gas supply apparatus 33, to the processing container 2, as processing gas. The pressure of the processing container 2 is maintained in the range of 1 Pa to 10 KPa. In the fourth embodiment, an object is to uniformly supply gas, and a gas storage space 13 is provided on an outer periphery of the processing container 2 between the processing gas supply apparatuses 32 and 33 and the processing container 2. The gas storage space 13 includes a plurality of gas holes (not illustrated) which is evenly formed in a circumferential direction so as to uniformly supply gas onto a wafer from a wall surface of the processing container 2 radially. Herein, as the number of the gas holes, two or more locations are preferably provided at a regular distance. The processing gas is supplied through the gas storage space 13 to improve circumferential uniformity of a processing atmosphere of the wafer.

Even in the fourth embodiment, the processing gas is dissociated by VUV light and an atom is attached to a resist film together therewith. Therefore, stress generated in a sample to be processed may be alleviated, long-period roughness having a period of 30 nm or more of a minute line may be significantly reduced, and unevenness generated on the surface or the side of the resist film formed on a semiconductor substrate is suppressed with high precision, and as a result, etching may be implemented.

### Fifth Embodiment

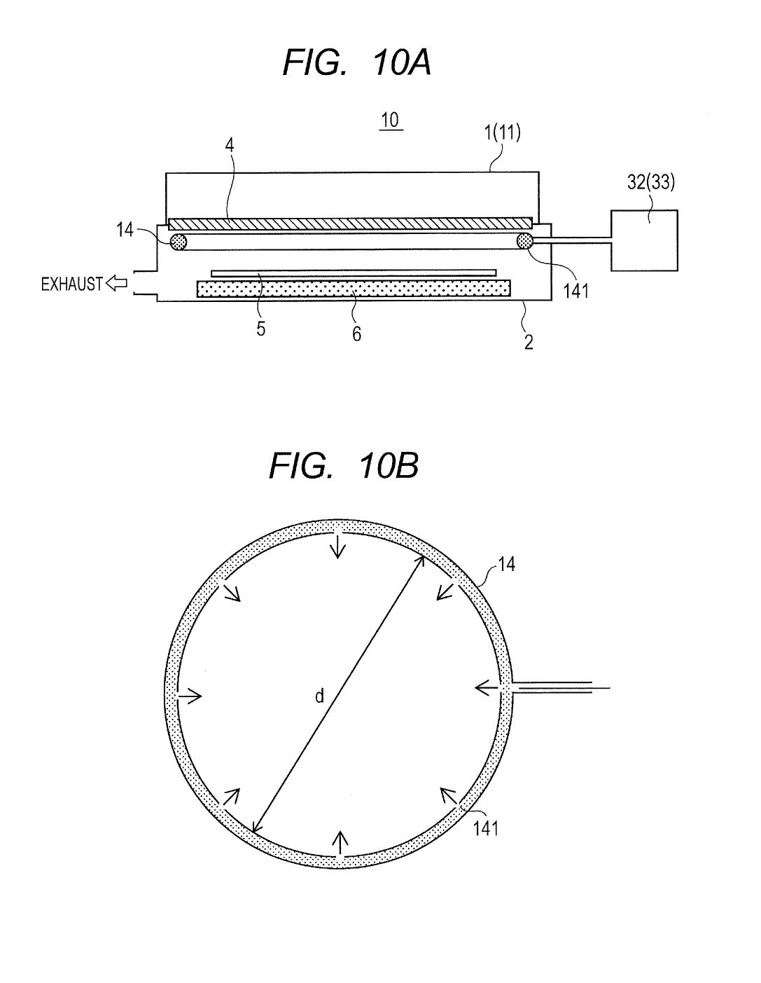

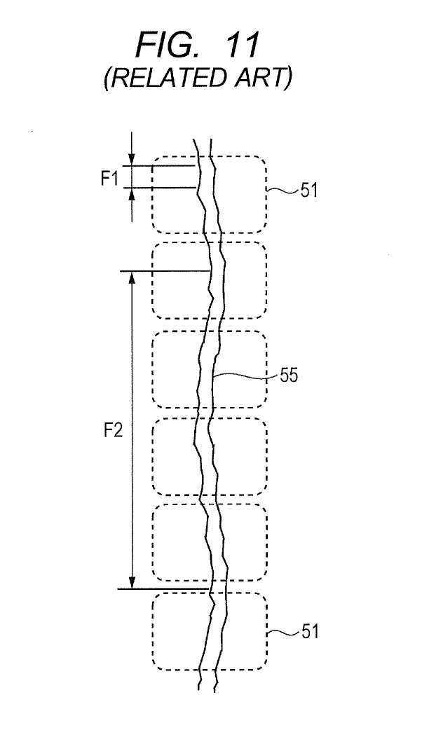

Subsequently, as a fifth embodiment of the present invention, a sample processing apparatus having another processing gas supply means for improving uniformity of a processing atmosphere will be described. FIG. 10A is a longitudinal cross-sectional view of a sample processing apparatus according to a fifth embodiment, and FIG. 10B is a plan view illustrating, in detail, a gas supply ring.

In the fifth embodiment, a gas supply ring 14 is provided in a processing container 2, as a means for uniformly supplying gas. In the case of the gas supply ring 14, gas holes are provided at a regular distance in a circumferential direction of the ring so as to uniformly supply gas onto the wafer radially, and the gas holes are provided at two or more locations. In the case where the gas supply ring 14 is provided between the light source unit 10 and the processing container 2, uniformity of irradiation intensity of VUV light may deteriorate due to a shielding effect of VUV light by the gas supply ring 14. As a result, in the case where an inner diameter d of the gas supply ring 14 is larger than an outer diameter of a processing wafer 5, a material configuring the gas supply ring 14 is not limited, and for example, the gas supply ring 14 may be made of stainless, aluminum, and the like, but in the case where the inner diameter d is smaller than the outer diameter of the processing wafer 5, synthetic quartz, MgF₂, CaF₂, LIF, sapphire, or the like, which VUV light having a wavelength of 172 nm, which is generated from the light source unit 10 may pass through, is required, as the material configuring the ring. SiCl₄ is supplied from a first processing gas supply apparatus 32 or hydrobromide (HBr) is supplied from a second processing gas supply apparatus 33, to the processing container 2, as processing gas. The pressure of the processing container 2 is maintained in the range of 1 Pa to 10 KPa.

Even in the fifth embodiment, stress generated in a sample to be processed may be alleviated, long-period roughness having a period of 30 nm or more of a minute line may be significantly reduced, and unevenness generated on the surface or the side of a resist film formed on a semiconductor substrate is suppressed with high precision, and as a result, etching may be implemented.

### Sixth Embodiment

Although (dry, liquid immersed) ArF resist pattern wafers have been used as the sample wafers in the first to fifth embodiments disclosed above, the sample wafer may be an EUV resist pattern wafer. The EUV resist pattern is highly required to reduce LWR and has a large merit in VUV curing, in order to be used in minute pattern processing. A wafer which is exposed by an exposer (an ArF exposer, an EUV exposer, or the like), developed, and resist-patterned is cured by uniformly supplying reactive gas to the vacuum ultraviolet light (VUV) apparatus, and roughness of the resist pattern is reduced, and thereafter, a base film of resist is etched with plasma, or the like by using the resist as a mask, thereby implementing minute processing having small long-period roughness. Further, the EUV resist pattern may be applied to LWR reduction after forming the pattern by a direct self assembly (DSA). After block copolymer coating, arrangement by annealing, and patterning by selective etching of dry etching or wet etching, the processing gas is uniformly supplied to the VUV light processing apparatus, the short-period roughness and long-period roughness of the resist pattern is reduced, and thereafter, the base film of the resist is etched with plasma or the like by using the resist after the LWR reduction as the mask, thereby implementing minute processing having small roughness.

Further, an application example of the VUV curing which is used to reduce the LWR of the resist pattern has been illustrated as an application of the present invention in each embodiment, but curing and modification of an organic material (particular, an application-based material) film may be used, such as Low-k film curing, anti-reflecting film curing, resist base film curing, curing of a multilayer mask material, or the like, as another application of the VUV light processing apparatus of the present invention. In addition, the present invention may be applied to curing and modification of an inorganic material (particularly, a film-forming material by evaporation, sputtering, CVD, or the like).

What is claimed is:

1. A method for processing a sample to be processed, with patterned resist, in a sample processing apparatus including a light source emitting vacuum ultraviolet light, a processing chamber having a stage therein and capable of irradiating the vacuum ultraviolet light having a wavelength of 200 nm or less to the sample to be processed, which is disposed on the stage, a processing gas supply apparatus introducing processing gas into the processing chamber, and a vacuum exhaust apparatus connected to an outlet port of the processing chamber, the method, comprising:
disposing the sample to be processed, with the patterned resist on the stage in the processing chamber;
supplying silicon tetrachloride (SiCl₄) or hydrobromide (HBr) into the processing chamber as processing gas; and
exciting the processing gas in some of the vacuum ultraviolet light by irradiating the vacuum ultraviolet light to the processing gas in the processing chamber, reacting an element of Si or Br contained in the excited processing gas and the resist with the remaining ultraviolet light, and alleviating stress generated in the resist while curing the resist.

2. The method for processing the sample according to claim 1, wherein:
the sample processing apparatus includes a pressure control unit controlling the pressure of the processing chamber, and
the pressure of the processing chamber is maintained in the range of 1 Pa to 10 KPa and the processing gas is excited by irradiating the vacuum ultraviolet light to the processing gas.

3. The method for processing the sample according to claim 2, wherein the sample is an ArF resist pattern wafer.

4. The method for processing the sample according to claim 2, wherein:
the sample is an EUV resist pattern wafer, and
the EVU resist pattern wafer is disposed in the processing chamber, the wafer is cured by supplying the processing gas, roughness of the resist pattern is reduced, and a base film of the resist is etched with plasma by using the resist as a mask.

5. A sample processing apparatus, comprising:
a light source emitting vacuum ultraviolet light;
a processing chamber having a stage therein and capable of irradiating the vacuum ultraviolet light having a wavelength of 200 nm or less to the sample to be processed, which is disposed on the stage;
a processing gas supply apparatus introducing processing gas into an irradiation area of the vacuum ultraviolet light in the processing chamber;
a vacuum exhaust apparatus connected to an outlet port of the processing chamber; and
a pressure control unit in a container controlling the pressure of the processing chamber,
wherein the processing gas is silicon tetrachloride (SiCl₄) or hydrobromide (HBr),
the sample to be processed is a sample having patterned resist, and
the processing gas is excited in some of the vacuum ultraviolet light by irradiating the vacuum ultraviolet light to the processing gas in the processing chamber, an element of Si or Br contained in the excited processing gas and the resist reacts with each other with the remaining ultraviolet light, and stress generated in the resist is alleviated while curing the resist.

6. The sample processing apparatus according to claim 5, wherein:
the pressure control unit in the container serves to control the pressure of the processing chamber depressurized by the vacuum exhaust apparatus, and
the resist is cured while maintaining the pressure of the processing chamber in the range of 1 Pa to 10 KPa.

7. The sample processing apparatus according to claim 6, wherein the processing gas supply apparatus has a gas distribution unit made of synthetic quartz, MgF₂, CaF₂, LIF, or sapphire which excimer light having a wavelength of 172 nm is able to pass through and supplies the processing gas to the processing chamber through the gas distribution unit.

8. The sample processing apparatus according to claim 6, further comprising:
a gas storage space provided on an outer periphery of the processing chamber between the gas supply apparatus and the processing chamber,
wherein a plurality of gas holes provided in a circumferential direction at a regular distance is provided in the gas storage space so as to uniformly supply the processing gas onto the sample to be processed from a wall surface of the processing chamber radially.
